(19) United States
(12) Patent Application Publication
(10) Pub. No.: US 2019/0056630 A1
(43) Pub. Date: Feb. 21, 2019

(54) DISPLAY DEVICE AND MANUFACTURING METHOD THEREOF

(71) Applicants: BOE TECHNOLOGY GROUP CO., LTD., Beijing (CN); ORDOS YUANSHENG OPTOELECTRONICS CO., LTD., Ordos (CN)

(72) Inventors: Hong LIU, Beijing (CN); Fengguo WANG, Beijing (CN); Dawei SHI, Beijing (CN); Zifeng WANG, Beijing (CN); Xinguo WU, Beijing (CN); Bo MA, Beijing (CN); Feng LI, Beijing (CN); Yuanbo LI, Beijing (CN); Zhixuan GUO, Beijing (CN); Cenhong DUAN, Beijing (CN); Jing ZHAO, Beijing (CN)

(21) Appl. No.: 16/001,646

(22) Filed: Jun. 6, 2018

(30) Foreign Application Priority Data
Aug. 17, 2017 (CN) 201721033702.5

(51) Int. Cl. G02F 1/1362; G02F 1/1368; H01L 27/12; H01L 21/285; G02F 1/1335; H05K 9/00

(52) U.S. Cl. CPC G02F 1/136204; G02F 1/1368; H01L 27/1262; H05K 9/0096; G02F 1/133512; G02F 1/133514; H01L 21/2855

(57) ABSTRACT

A display device is provided, including an array substrate and an opposite substrate, a fan-out gate array formed on the array substrate and a transparent conductive material layer overlying the fan-out gate array; and a fan-out region formed on the opposite substrate and a base layer formed on the fan-out region.

### CROSS REFERENCE TO RELATED APPLICATIONS

The present application claims the priority of the Chinese Patent Application No. 201721033702.5 entitled “Display” filed with SIPO on Aug. 17, 2017, which is incorporated herein by reference in its entirety.

### TECHNICAL FIELD

Embodiments of the present disclosure relate to a display device and a manufacturing method thereof.

### BACKGROUND

With the development of electronic liquid crystal display technology, liquid crystal displays (LCDs) and products based on extension of LCDs have been applied widely in electronic products.

In a LCD production, defects of screen display, such as color lines and white lines, often occur in the power-on stage, which significantly reduces yields of display products.

### SUMMARY

Embodiments of the present disclosure provide a display device and manufacturing method thereof.

At least one embodiment of the present disclosure provides a display device, comprising: an array substrate and an opposite substrate; a fan-out gate array provided on the array substrate and a transparent conductive layer overlying the fan-out gate array; and a fan-out region provided on the opposite substrate and a base layer provided on the fan-out region, wherein the transparent conductive layer faces the base layer.

For example, the transparent conductive layer comprises indium tin oxide.

For example, the indium tin oxide layer overlies the fan-out gate array.

For example, the display device further comprises a liquid crystal display, the liquid crystal display comprising a liquid crystal layer disposed between the array substrate and the opposite substrate.

At least one embodiment of the present disclosure provides display device, manufacturing method of a display device, comprising: providing an array substrate and an opposite substrate; forming a fan-out gate array layer on the array substrate; forming a transparent conductive layer on the fan-out gate array layer to allow the transparent conductive layer to overly the fan-out gate array layer; forming a fan-out region on the opposite substrate; and forming a base layer on the fan-out region; the transparent conductive layer facing the base layer.

For example, the transparent conductive layer is formed on the fan-out gate array with a mask by a sputtering process.

### BRIEF DESCRIPTION OF THE DRAWINGS

Embodiments of the present disclosure will be described in more detail below with reference to accompanying drawings to allow an ordinary skill in the art to more clearly understand embodiments of the present disclosure, in which:

FIG. 1 is a structural block diagram of a liquid crystal display device;

FIG. 2 is a schematically structural diagram of a display device according to an embodiment of the present disclosure;

FIG. 3 is a flow chart of a method for manufacturing a display device according to an embodiment of the present disclosure; and

FIG. 4 is a flow chart of a method for manufacturing a display device according to another embodiment of the present disclosure.

### DETAILED DESCRIPTION

Technical solutions of the embodiments will be described in a clearly and fully understandable way in connection with the drawings related to the embodiments of the disclosure. It is apparent that the described embodiments are just a part but not all of the embodiments of the disclosure. Based on the described embodiments herein, those skilled in the art can obtain other embodiment(s), without any creative work, which shall be within the scope of the disclosure.

Without conflict, embodiments and elements in embodiments in the present application may be combined arbitrarily, and some conventional structures and features are omitted for clear description of the present disclosure.

Steps shown in flow charts of the drawings may be executed in a computer system, such as a set of computer executable instructions. Further, for example, although logical orders are shown in the flow charts, the illustrated or described steps may be executed in orders other than those shown herein in certain cases.

For defective screen display, inventors of the present application found out that an induced electric field might occur in the array fan-out gate region of a liquid crystal display screen which acts on the basement membrane (BM) of the color filter (CF) field to accumulate electric charges that enter pixel region, causing poor color lines on powering-on and impacting screen display. FIG. 1 is a structural diagram of a liquid crystal display. As shown in FIG. 1, an induced electric field 1-2 is generated in the array fan-out gate region 1-1, which acts on the BM 1-3 of CF to accumulate charges 1-4 that enter the pixel region, resulting in screen display defects, such as color lines and white lines.

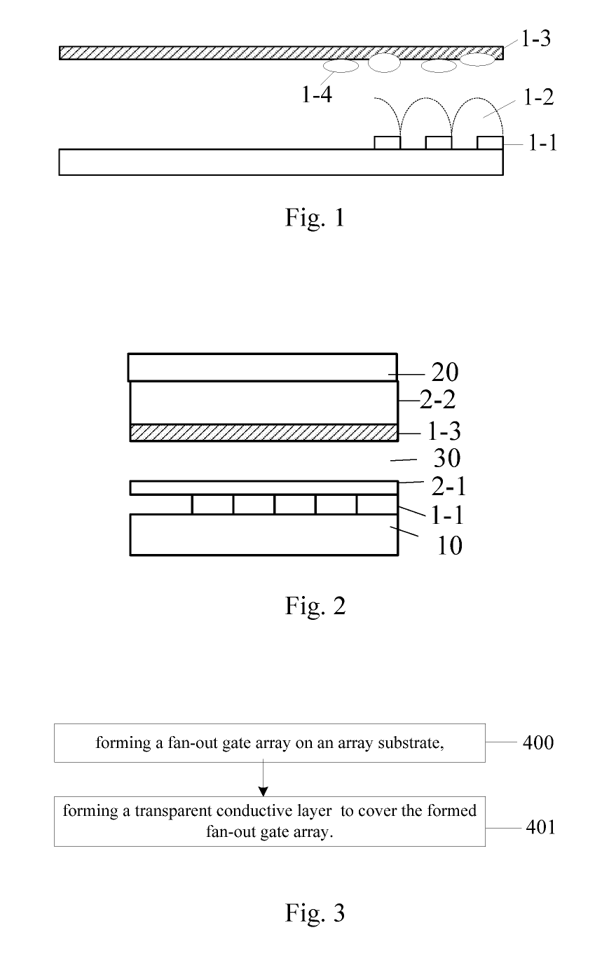

FIG. 2 is a schematically structural diagram of a display device according to an embodiment of the present disclosure. As shown in FIG. 2, the display device includes an array substrate 10 and an opposite substrate 20, an array fan-out gate region 1-1 disposed on the array substrate 10 and a transparent conductive layer 2-1 overlying the array fan-out gate region 1-1, a fan-out region 2-2 and a base layer 1-3 disposed on the opposite substrate 20.

Fir example, material of the base layer includes Black Matrix resin which can shield light, which has advantages, such as low cost and low reflectivity.

For example, the substrate may be a plastic substrate, a glass substrate, or a quartz substrate.

For example, the opposite substrate is a color filter substrate.

In embodiments of the present disclosure, the induced electric field 1-2 generated by the array fan-out gate region 1-1 is shielded by the transparent conductive layer 2-1 to avoid defects, such as white lines and color lines, upon powering-on, in this way, the screen display quality is improved.

It is to be noted that the display device according to an embodiment of the present disclosure may further include a display driver, and other layers of the display device, such as a liquid crystal layer, may be further disposed between the transparent conductive layer 2-1 and the base layer 1-3.

For example, the transparent conductive layer according to the embodiment of the present disclosure is made of a transparent conductive material including indium tin oxide.

It is to be noted that indium tin oxide is only an example of the present disclosure, and the transparent conductive material according to embodiment(s) of the present disclosure may include other transparent conductive materials used for manufacturing display devices, such as IZO (indium zinc oxide), carbon nano-tube conductive material, grapheme, zinc oxide doped with aluminum.

For example, in embodiments of the present disclosure, the array fan-out gate region 1-1 is covered with indium tin oxide by a sputtering process, and forming a transparent conductive layer 2-1.

For example, in embodiments of the present disclosure, the array fan-out gate region is covered with indium tin oxide by a mask through a sputtering process, and forming a transparent conductive layer.

For example, the display device according to an embodiment of the present disclosure includes a liquid crystal display device.

It is to be noted that the liquid crystal display device herein includes display devices developed based on the extension of liquid crystal display device.

In the display device according to the embodiments of the present disclosure, screen display is improved by providing an array fan-out gate and a transparent conductive layer overlying the array fan-out gate as well as a base layer and a fan-out region, and yield of the display products is improved.

FIG. 3 is a flow chart of a method for manufacturing a display device according to an embodiment of the present disclosure, which, as shown in FIG. 3, includes the following steps.

In step 400, a fan-out gate array is formed on an array substrate.

It is to be noted that the method for forming the fan-out gate array may be any implementation method in the art and will not be repeated herein.

In step 401, a transparent conductive layer is formed to cover the formed fan-out gate array.

In embodiments of the present disclosure, the induced electric field generated by the array fan-out gate region is shielded by the transparent conductive layer to avoid defects, such as white lines and color lines, upon powering-on, in this way, the screen display quality is improved.

For example, the transparent conductive material used according to the embodiment of the present disclosure includes indium tin oxide, however, embodiments of the present disclosure are not limited thereto, and the transparent conductive material according to the embodiments of the present disclosure may include other transparent conductive materials used for manufacturing display devices, such as IZO (indium zinc oxide), carbon nano-tube conductive material, grapheme, zinc oxide doped with aluminum.

For example, in an embodiment of the present disclosure, covering the transparent conductive layer on the formed fan-out gate array includes: forming the indium tin oxide layer and covering the fan-out gate array by a sputtering process.

For example, in an embodiment of the present disclosure, covering the transparent conductive layer on the formed fan-out gate array includes: forming the indium tin oxide layer and covering the fan-out gate array with a mask by a sputtering process, to form the transparent conductive layer.

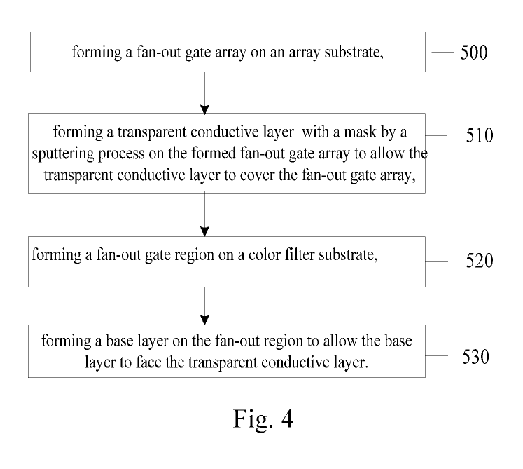

FIG. 4 is a flow chart of a method for manufacturing a display device according to another embodiment of the present disclosure, which, as shown in FIG. 4, includes the following steps.

In step 500, a fan-out gate array is formed on an array substrate.

The method for forming the fan-out gate array may be any implementation method in the art and will not be repeated herein.

In step 510, a transparent conductive layer is formed with a mask by a sputtering process on the formed fan-out gate array to allow the transparent conductive layer to cover the fan-out gate array.

For example, in the embodiment of the present disclosure, a transparent conductive material, such as indium tin oxide is used to form the transparent conductive layer, however, embodiments of the present disclosure are not limited thereto, and the transparent conductive material according to the embodiments of the present disclosure may include other transparent conductive materials used for manufacturing display devices, such as IZO (indium zinc oxide), carbon nano-tube conductive material, grapheme, zinc oxide doped with aluminum.

In step 520, a fan-out gate region is formed on a color filter substrate.

In step 530, a base layer is formed on the fan-out region to allow the base layer to face the transparent conductive layer.

For example, the display device according to the embodiment(s) of the present disclosure include(s) a liquid crystal display device.

It is to be noted that the liquid crystal display device herein includes display devices developed based on the extension of liquid crystal display device.

Embodiments of the present disclosure improve the screen display quality and yield of display products.

Those of ordinary skill in the art may appreciate that all or some steps in the above-mentioned method may be implemented by instructing related hardware, such as processors, with programs that may be stored in computer readable storage media, such as read only memories, magnetic disks or optical disks. Optionally, all or some steps of the above-described embodiments may be implemented by one or more integrated circuits. Accordingly, each module/unit in the above-described embodiments may be implemented with hardware, for example, implementing corresponding functions by integrated circuits, or implemented in the form of software functional modules, e.g., implementing corresponding functions by executing programs/instructions stored in memories with processors. Embodiments of the present disclosure are not limited to any specific combinations of hardware and software.

The foregoing is only the exemplary embodiments of the present disclosure, and the scope of the present disclosure is not limited thereto. A person of ordinary skill in the art can make various changes and modifications without departing from the spirit of the present disclosure, and such changes and modifications shall fall into the scope of the present disclosure.

What is claimed is:

1. A display device, comprising:
an array substrate and an opposite substrate,
a fan-out gate array provided on the array substrate and a transparent conductive layer overlying the fan-out gate array; and
a fan-out region provided on the opposite substrate and a base layer provided on the fan-out region,
wherein the transparent conductive layer faces the base layer.

2. The display device of claim 1, wherein the transparent conductive layer comprises indium tin oxide.

3. The display device of claim 2, wherein the indium tin oxide layer overlies the fan-out gate array.

4. The display device of claim 1, further comprising a liquid crystal display, the liquid crystal display comprising a liquid crystal layer disposed between the array substrate and the opposite substrate.

5. A manufacturing method of a display device, comprising:
providing an array substrate and an opposite substrate;
forming a fan-out gate array layer on the array substrate;
forming a transparent conductive layer on the fan-out gate array layer to allow the transparent conductive layer to overly the fan-out gate array layer;
forming a fan-out region on the opposite substrate; and
forming a base layer on the fan-out region;
wherein the transparent conductive layer faces the base layer.

6. The manufacturing method of the display device of claim 5, further comprising:
forming the transparent conductive layer on the fan-out gate array with a mask by a sputtering process.
